(19) United States
(12) Patent Application Publication
(10) Pub. No.: US 2006/0018185 A1
(43) Pub. Date: Jan. 26, 2006

(54) Memory control apparatus and electronic apparatus

(76) Inventors: Yuuzi Kurotsuchi, Ukyo-Ku (JP); Sachihiro Ohira, Ukyo-Ku (JP)

Correspondence Address: CANTOR COLBURN, LLP, 55 GRIFFIN ROAD SOUTH, BLOOMFIELD, CT, 06002, US

(21) Appl. No.: 11/124,028

(22) Filed: May 6, 2005

Related U.S. Application Data
(63) Continuation of application No. PCT/JP04/10861, filed on Jul. 29, 2004.

(30) Foreign Application Priority Data
Nov. 7, 2003 (JP) JP2003-379181

(51) Int. Cl. G11C 8/00

(52) U.S. Cl. 365/233

(57) ABSTRACT

In order to control a synchronous memory, a synchronous signal is required. In most cases, a clock signal is used for this purpose. This approach has room for improvement in power consumption etc. A synchronous signal generating circuit 22 generates a synchronous signal for a synchronous memory from an asynchronous access signal. A primary access circuit 24 generates a command that fulfills a necessary timing relation with respect to the synchronous signal. A subsidiary access circuit 26 generates an access signal on behalf of a data processing entity other than a host CPU. A RAM 30 is a synchronous memory. Since the synchronous signal generating circuit 22 and the subsidiary access circuit 26 generate a synchronous access signal, valid access to the synchronous memory is guaranteed, while presenting an appearance of controlling an asynchronous memory.

### CROSS-REFERENCE TO RELATED APPLICATION

The present application is a continuation of PCT/JP2004/010861, filed on Jul. 29, 2004, the entire contents of which are incorporated herein by reference, and which claims the benefit of the date of the earlier filed Japanese Patent Application No. JP 2003-379181 filed on Nov. 7, 2003.

### TECHNICAL FIELD

The present invention relates to a memory control apparatus and an electronic apparatus and, more particularly, to a memory control apparatus for a synchronous memory requiring a synchronous signal for access and an electronic apparatus using the memory control apparatus.

### BACKGROUND TECHNOLOGY

A dynamic random access memory (DRAM) is adapted for large capacity and is widely used as a main memory for electronic apparatuses such as computers. Historically, DRAMs of an asynchronous type that do not require a clock or other synchronous signals for access are main stream. With the increase of operating frequency of an entity such as a CPU accessing the memory, it has become difficult to apply asynchronous control, facilitating the development and acceptance of a synchronous type. In controlling a DRAM of a synchronous type, data can be read out sequentially in a read cycle, by ensuring that active edges of a synchronous signal occur sequentially at intervals that guarantee an access time. Similarly, in a write cycle, data can be written sequentially under the control of synchronous signal. Therefore, DRAMs of a synchronous type are of great use in increasing the speed of execution of applications that sequentially read and write a relatively large volume of data. For example, multimedia processes or large-scale programs used by a CPU benefit from the synchronous type. Patent documents 1 and 2 propose an improvement in data transfer by using a dual-port memory.
[patent document 1]
   JP 1-61133 A
[patent document 2]
   JP 63-302654 A

### DISCLOSURE OF THE INVENTION

Synchronous memories including DRAMs of a synchronous type (hereinafter, simply referred to as “synchronous memories”) facilitates high-speed access but, on the other hand, requires a clock signal that originates a synchronous signal. To improve the speed of access, a clock signal of a higher frequency is required. The use of a high-speed clock is accompanied by generally unfavorable results including an increase in power consumption, an increase in radiated emission noise, difficulty of running wires and difficulty of avoiding malfunction due to lacing.

The present invention has been done in view of the aforementioned problems and its object is to provide a memory control apparatus and an electronic apparatus using the same which is capable of controlling a synchronous memory without using a clock signal or only using it on a minimum basis.

The memory control apparatus according to the present invention comprises: a synchronous signal generating circuit which receives an asynchronous access signal output from an accessing entity that assumes an asynchronous memory not requiring a synchronous signal for access, and which generates a synchronous signal for a synchronous memory requiring a synchronous signal for access, by referring to a point of change in the asynchronous access signal; and a primary access circuit which generates a synchronous access signal by processing the asynchronous access signal to fulfill a timing requirement required by the synchronous memory.

The accessing entity is, for example, a host CPU. In an alternative perspective, the accessing entity is a circuit that generates an asynchronous access signal as a time-varying signal, such as a command signal, which is timed to vary, instead of generating a fixed-level signal, i.e., a signal that is maintained at “1” or “0” unless switched from one state to the other using, for example, a register. By utilizing the timing of the varying signal, a synchronous signal is generated relatively easily. According to the structure described above, a synchronous signal is generated from an asynchronous signal. Therefore, a clock signal is not necessary and the aforementioned problems are solved. When a clock signal is not used, an access cycle need not be of a duration which is an integral multiple of a clock cycle. It is therefore possible to minimize the duration of access cycle as required.

The memory control apparatus may further comprise: an arbiter circuit which acquires a right to access to the synchronous memory for a data processing entity different from the access entity; and a subsidiary access circuit which generates an access signal for the data processing entity to access the synchronous memory. The subsidiary access circuit may generate the access signal to access the synchronous memory, using a clock signal.

The “data processing entity” may not be an intelligent entity but a functional unit that merely transmits and receives data. In this case, the functional unit may not be capable of generating an asynchronous access signal on its own or merely capable of outputting a fixed-level signal. As such, triggers for timing the generation of a synchronous signal are not available. Thus, a clock signal may be utilized in this specific case. In any way, the inventive structure enables access from a data processing entity to a synchronous memory, thereby broadening the application of a synchronous memory and promoting the usability for users.

The synchronous signal generating circuit may generate, in a read cycle, a synchronous signal so that an effective synchronous edge occurs after a relatively brief period of time elapses since the point of change, and generates, in a write cycle, a synchronous signal so that an effective synchronous edge occurs after a relatively long period of time elapses since the point of change. In a synchronous memory, a read operation or a write operation is often initiated by a synchronous edge. According to the inventive structure, the initiation of a read cycle is advanced in time so that a read cycle is shortened. In contrast, the initiation of a write operation can be delayed so that a relatively long time for setting up write data is provided.

The present invention according to another aspect is directed to an electronic apparatus. The electronic apparatus according to this aspect comprises: a host CPU; a memory control apparatus; an image capturing unit; and a display unit, wherein the memory control apparatus comprises: a synchronous memory requiring a synchronous signal for access; a circuit which receives an asynchronous access signal from the host CPU and generates a synchronous access signal required by the synchronous memory by generating a synchronous signal from the asynchronous access signal; a circuit which receives image data captured by the image capturing unit and writes the image data in the synchronous memory; a circuit which reads data from the synchronous memory and causes the display unit to display the read data.

According to this structure, the aforementioned advantages of the memory control apparatus are enjoyed and the diversification of applications of a synchronous memory is promoted. The electronic apparatus is suitable for applications such as a cell phone provided with an image capturing unit in which mounting space is limited and requirements in power consumption is severe.

The inventive memory control circuit is advantageous in respect of power consumption etc. In the inventive electronic apparatus, these merits are enjoyed.

### BRIEF DESCRIPTION OF THE DRAWINGS

FIG. 1 illustrates the overall structure of a portable electronic apparatus according to an embodiment;

FIG. 2 illustrates the internal structure of a memory control apparatus according to the embodiment;

FIG. 3 illustrates the internal structure of a synchronous signal generating circuit of the memory control apparatus;

FIG. 4 illustrates the internal structure of a primary access circuit of the memory control apparatus;

FIG. 5 illustrates the internal structure of an arbiter of the memory control apparatus;

FIG. 6 illustrates the internal structure of a subsidiary access circuit of the memory control apparatus;

FIG. 7 is a timing chart illustrating the operation of the memory control apparatus according to the embodiment; and

FIG. 8 is a timing chart illustrating the operation of the memory control apparatus according to the embodiment.

### BEST MODE OF CARRYING OUT THE INVENTION

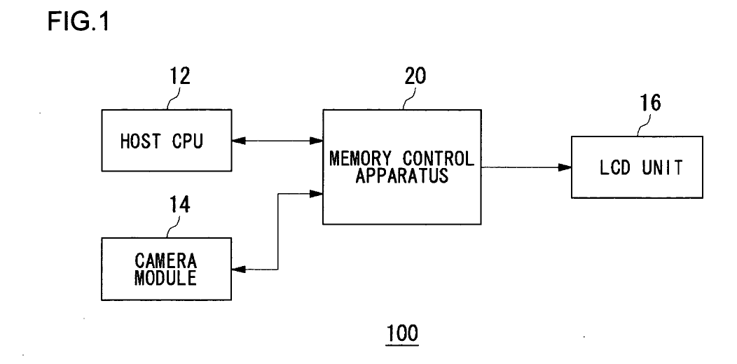

FIG. 1 illustrates the overall structure of a portable electronic apparatus 100 according to an embodiment. The portable electronic apparatus 100 is provided with a host CPU 12, a camera module 14, an LCD unit 16 and a memory control apparatus 20. The memory control apparatus 20 controls access to a memory (not shown) built in the memory control apparatus 20 for the CPU 12, the camera module 14 and the LCD unit 16. The camera module 14 is provided with a CCD (not shown) and stores data obtained by capturing an image to the memory of the memory control apparatus 20. The memory control apparatus 20 performs memory write control forth is purpose. The LCD unit 16 sequentially displays data read out from the memory of the memory control apparatus 20 and subjected to necessary conversion.

In this structure, the host CPU 12 generates a signal on its own for accessing a memory assumed to be an asynchronous memory. That is, the CPU 12 does not generate a synchronous signal such as a clock signal. The memory built in the memory control apparatus 20 is a synchronous memory which naturally requires a synchronous signal for access. The memory control apparatus 20 is therefore provided with a bridge function that converts an asynchronous access signal into a synchronous access signal. As described later, the bridge function does not require the input of an external clock signal for access from the host CPU 12. More specifically, the bridge function generates, in place of a clock signal, a synchronous signal using an edge of an asynchronous access signal generated by the host CPU 12.

The camera module 14 sequentially transfers the data obtained by capturing an image to the memory of the memory control apparatus 20. The camera module 14 is not of an intelligent structure as the host CPU 12 and does not generate a signal for accessing the memory on its own. Therefore, the memory control apparatus 20 generates an access signal on behalf of the camera module 14 in order to import data from the camera module 14. The memory control apparatus 20 is provided with an arbiter function so as to prevent the access from the host CPU 12 and the import of data from the camera module 14 from contending.

The LCD unit 16 sequentially reads data subjected to conversion and read out from the memory of the memory control apparatus 20 for display. The LCD unit 16 is also not of an intelligent structure either and does not generate a signal to access the memory on its own. Therefore, the memory control apparatus 20 generates an access signal on behalf of the LCD unit 16. As described, according to the portable electronic apparatus 100, the memory control apparatus 20 has a built-in synchronous memory and applies efficient memory control for the host CPU 12, the camera module 14 and the LCD unit 16 that access the synchronous memory, thereby promoting the efficient use of the memory with a compact structure. Since a clock signal is not necessary at least to convert the asynchronous access signal from the host CPU 12 into a synchronous access signal, the access cycle from the host CPU 12 is not constrained by the cycle of clock signal, enabling the performance of the host CPU 12 and the memory built in the memory control apparatus 20 to be maximized. The camera module 14 does not even generate an asynchronous access signal for data transfer. Therefore, the memory control apparatus 20 according to the embodiment generates a synchronous signal using an external clock signal.

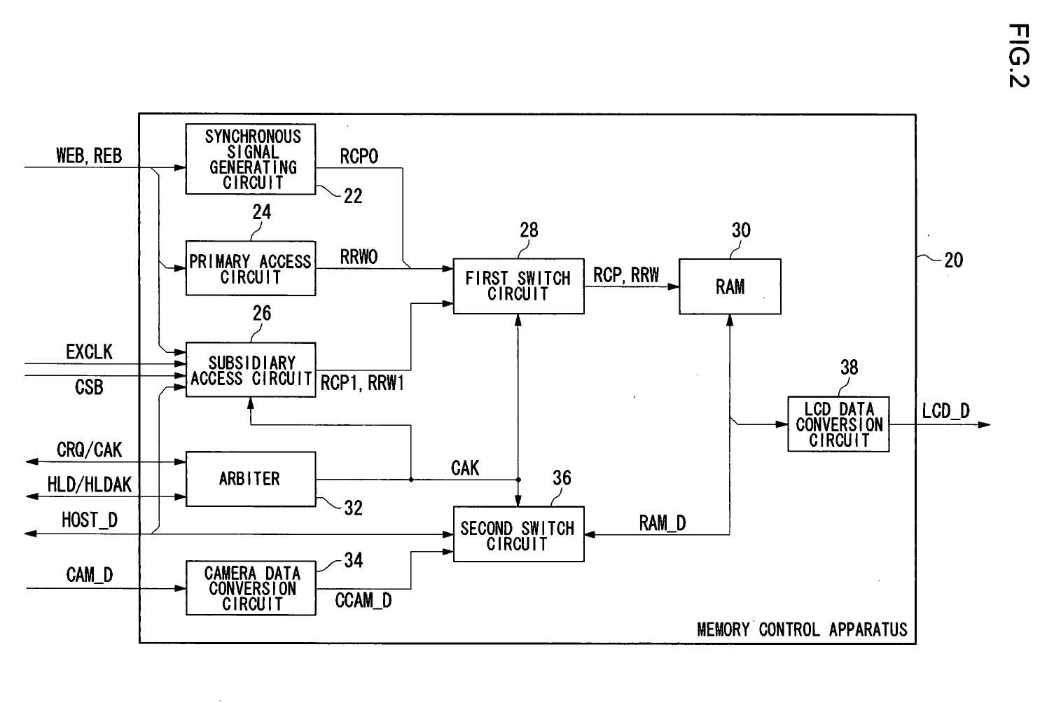

FIG. 2 illustrates the internal structure of the memory control apparatus 20 in detail. A description will be given of the names of signals illustrated in the figure. In the signals listed below, the names ending with “B” identify active-low signals and the names not ending with “B” are active-high signals.
WEB: asynchronous memory write signal from the host CPU 12.
REB: asynchronous memory read signal from the host CPU 12.
EXCLK: clock signal input from an external source.
CSB: chip select signal for writing a command in the subsidiary access circuit 26.
CRQ/CAK: CRQ denotes a bus request signal issued from the camera module 14 in order to transfer data from the camera module 14 to the memory, and CAK denotes an acknowledgement signal in response to the bus request.
HLD/HLDAK: HLD denotes a request signal for putting the host CPU 12 on hold while data is being transferred from the camera module 14, and HLDAK denotes a signal brought to be active when the host CPU 12 is actually put on hold in response to the request signal.
HOST_D: data bus for host CPU 12 data.
CAM_D: data bus for data transferred from the camera module 14.
RCPO: synchronous signal generated for access from the host CPU 12.
RRWO: read or write signal indicating a timing relation required by RCPO for access from the host CPU 12.
RCP1: synchronous signal required for access to data from the camera module 14.
RRW1: read or write signal required for access from the camera module 14 and fulfilling a predetermined relation with RCP1.
CCAM_D: data signal obtained by applying a predetermined process to CAM_D
RCP: synchronous signal required for access to the synchronous memory (hereinafter, also referred to as “RAM”).
RRW: read or write signal required for access to the RAM
RAM_D: data bus for RAM data
LCD_D: data bus for display data to be output to the LCD

Given above is a list of signals. Hereinafter, the signals will be identified by alphabetical abbreviations. Access to the RAM is not only initiated by the host CPU 12 and the camera module 14 but also occurs when data is output to the LCD unit 16. However, since the process for the LCD unit 16 is practically identical with the generation of access signal for the camera module 14, a simplified description will be given below assuming that access to the RAM is initiated by the two entities, i.e., the host CPU 12 and the camera module 14.

The synchronous signal generating circuit 22 of the memory control apparatus 20 receives WEB and REB and generates RCPO by referring to edges of these asynchronous access signals. The primary access circuit 24 receives WEB and generates RRWO. The synchronous signal generating circuit 22 and the primary access circuit 24 constitute a signal conversion circuit for the host CPU 12.

The subsidiary access circuit 26 receives EXCLK and CAK so as to generate RCP1 and RRW1 from the received signals. Since the camera module 14 is incapable of generating an access signal on its own, the subsidiary access circuit 26 functions as a known direct memory access controller (DMAC). As such, read and write commands as well as the number of bytes transferred are set in the subsidiary access circuit 26. The subsidiary access circuit 26 is fed CSB, HOST_D and WEB, CSB being used to select the subsidiary access circuit 26 as a device. Since the function of DMAC is known in the art, the description thereof will be omitted in the following description.

The arbiter 32 is an arbitration circuit for switchably allowing the host CPU 12 or the camera module 14 to access the RAM. The arbiter 32 outputs HLD to the host CPU 12 when receiving CRQ. When HLDAK is returned from the host CPU 12, the arbiter activates CAK. CAK is input to the subsidiary access circuit 26, a first switch circuit 28 and a second switch circuit 36. A camera data conversion circuit 34 applies a process such as color conversion to captured image data input from the camera module 14, and outputs the processed data to the second switch circuit 36.

When the entity accessing the RAM is the host CPU 12, the first switch circuit 28 outputs RCPO as RCP. When the entity accessing the RAM is the camera module 14, the first switch circuit 28 outputs RCP1 as RCP. Similarly, the first switch circuit 28 selects one of RRWO and RRW1 and outputs the selected one as RRW. When CAK is low, i.e., inactive, RCPO and RRWO are output as RCP and RRW, respectively. When CAK is active, RCP1 and RRW1 are output as RCP and RRW, respectively.

The second switch circuit 36 connects the buses HOST_D and RAM_D to each other. In contrast, when CAK is active, the second switch circuit 36 connects the bus of CCAM_D to the bus of RAM_D. As described, the first switch circuit 28 and the second switch circuit 36 switch between commands and between buses, respectively, depending on the entity accessing the RAM.

The RAM 30 samples RRW at the rising edge of RCP. When RRW is high, a read operation is performed. When RRW is low, a write operation is performed. An LCD data conversion circuit 38 converts data read from the RAM 30 into display data. The converted data is output to the LCD unit 16 as LCD_D.

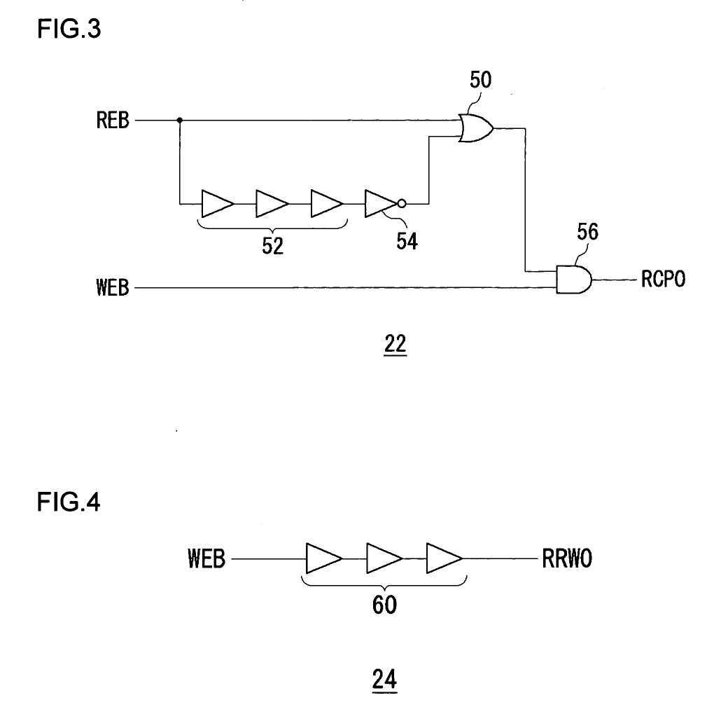

FIG. 3 illustrates the internal structure of the synchronous signal generating circuit 22. REB is connected to one input of an OR gate 50 and input to a delay gate 52. The output of the delay gate 52 is input to an inverter 54. The output of the inverter 54 is connected to the other input of the OR gate 50. The output of the OR gate 50 is connected to one input of an AND gate 56. WEB is connected to the other input of the AND gate 56. The output of the AND gate 56 represents RCPO. When WEB goes active, the synchronous signal generating circuit 22 according to this structure directly outputs WEB to RCP. When REB goes active, the synchronous signal generating circuit 22 generates a pulse that causes RCPO to go low for a predetermined period of time. The rising edge of RCPO has significance as a synchronous signal. Accordingly, when WEB goes active, the synchronous signal goes active relatively slowly. In contrast, when REB goes active, the synchronous signal goes active relatively fast. As a result, the initiation of a read operation in a read cycle is advanced in time. Therefore, a read cycle as a whole is shortened.

FIG. 4 illustrates the internal structure of the primary access circuit 24. WEB is input to a delay gate 60. The output of the delay gate 60 represents RRWO. This structure generates RRWO by delaying WEB. Therefore, a hold time in which RRWO in response to a delay in the rising edge of RCPO is provided.

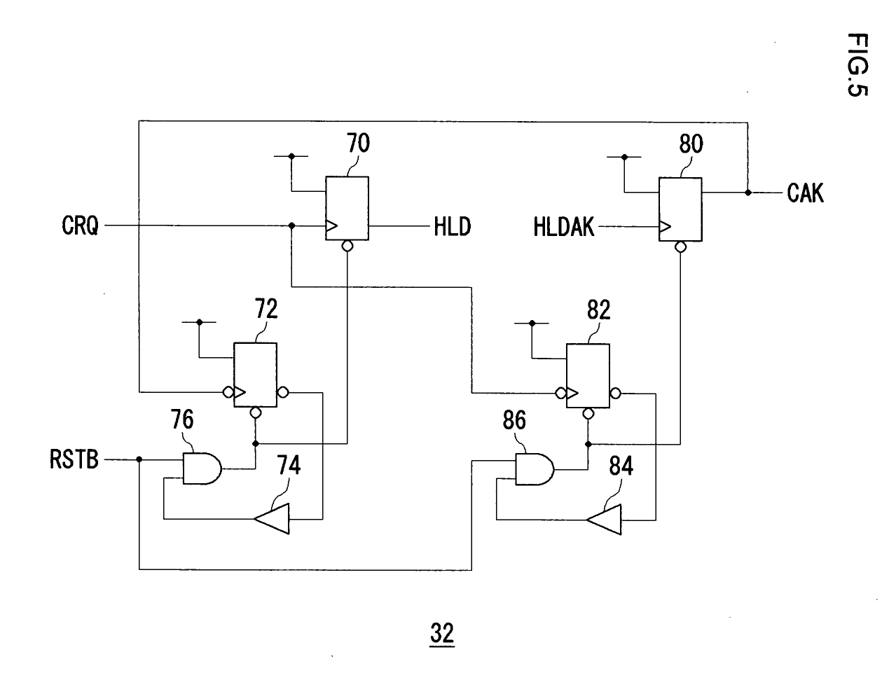

FIG. 5 illustrates the internal structure of the arbiter 32. CRQ is connected to the clock input of a flip-flop 70. The data input of the flip-flop 70 is pulled up. Similarly, the reset is connected to the output of a first AND gate 76. The output of the flip-flop 70 represents HLD.

The data input of a second flip-flop 72 is also pulled up. Further, the reset is connected to the output of the first AND gate 76. The flip-flop 72 is negative-triggered and its clock input is CAK. The inverting output of the flip-flop 72 is coupled through a delay gate 74 to one input of a first AND gate 76. The other input of the first AND gate 76 is fed RSTB, which is a system reset signal. According to the structure described above, the first flip-flop 70 and the second flip-flop 72 are reset by RSTB at initialization. Normally, HLD is low. When CRQ goes high, HLD goes high. When CAK goes from high to low, the second flip-flop 72 responds to it so that the inverting output thereof becomes low. This signal resets the second flip-flop 72 itself via the delay gate 74 and the first AND gate 76. As a result, the first flip-flop 70 is also reset so that HLD returns low. That is, the second flip-flop 72 is provided to generate a self-reset pulse.

The structure of a third flip-flop 80 is the same as that of the first flip-flop 70. The clock input of the third flip-flop 80 is HLDAK and the output thereof represents CAK. The structure of the fourth flip-flop 82 is the same as that of the second flip-flop 72 and its inverting clock input is CRQ. According to the structure described above, HLD goes active promptly when CRQ goes active. In response to this, when HLDAK goes active, CAK goes active. As a result, the entity accessing the RAM is switched to the camera module 14. Conversely, when data transfer of the camera module 14 is completed, CRQ goes inactive and CAK promptly goes inactive in response to this. HLD then goes inactive.

As a result, HLDAK goes inactive so that the accessing entity is switched back to the host CPU 12.

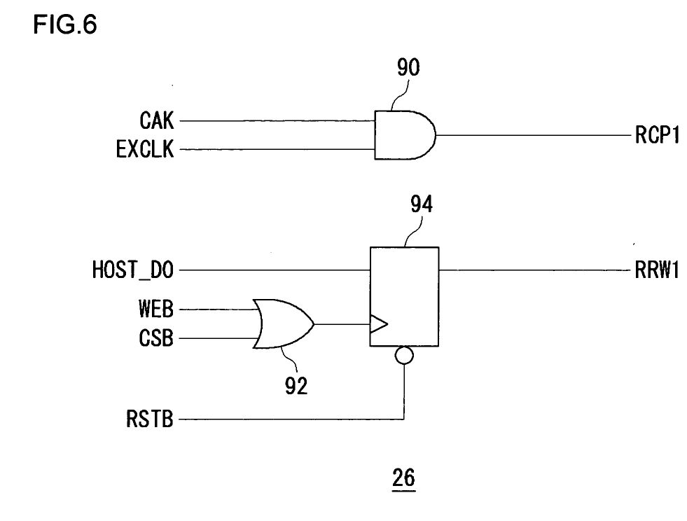

FIG. 6 illustrates the internal structure of the subsidiary access circuit 26. CAK and EXCLK are input to an AND gate 90. The output of the AND gate 90 represents RCP1. HOST_D0, i.e., the least significant bit from HOST is input to the data input of a flip-flop 94. The output of an OR gate 92 is fed to the clock input of the flip-flop 94. The inputs of the OR gate 92 are WEB and CSB. RSTB is connected to the reset input of the flip-flop 94. The output of the flip-flop 94 represents RRW1. Accordingly, while CAK remains active, EXCLK is directly output as RCP1. Whether data transfer by the camera module 14 is read or write is set in the register of the flip-flop 94. The OR gate 92 enables writing in the register. In the case of FIG. 6, when “1” is written in the flip-flop 94, a read operation is designated. When “0” is written, a write operation is designated.

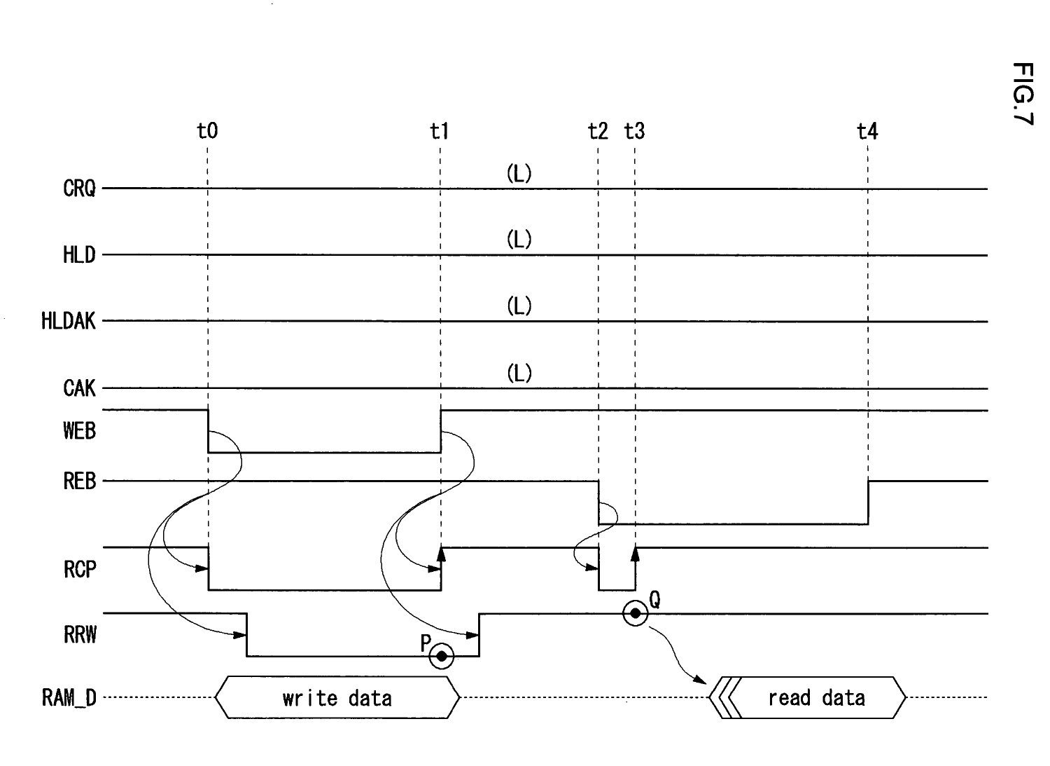

A description will now be given of the operation according to the structure described above. FIG. 7 is a timing chart for memory access occurring when the accessing entity is the host CPU 12. An access request from the camera module 14 is not occurring so that CRQ, HLD, HLDAK and CAK are maintained low. In this state, the host CPU 12 requests writing in the RAM. That is, WEB goes from high to low at time t0. As a result, RCP goes from high to low. In contrast, RRW goes low with a delay with respect to WEB. Write data output from the host CPU 12 appears in RAM_D via HOST_D and the second switch circuit 36. Writing into the RAM 30 is performed at time t1 when WEB goes from low to high. More accurately, WEB goes from low to high at time t1. In response to this, RCP goes from low to high. The data appearing in RAM_D at this moment is written into the RAM 30. In this process, a write cycle is initiated as a result oft RRW being low at time t1 (point P in the figure).

A description will now be given of read access by the host CPU 12. The CPU 12 starts read access to the RAM 30 at time t2. That is, REB goes from high to low at time t2. In response to this, a short low pulse occurs in RCP. RRW is sampled at time t3 when the low pulse is completed (Q in the figure). This initiates a read cycle. As a result, read data is output from the RAM 30 after a predetermined access time elapses since t3. The host CPU 12 samples the read data at time t4. Described above are read access and write access from the host CPU 12 to the RAM 30. As illustrated, access to the RAM 30, a synchronous memory, is achieved due to operation of the the memory control apparatus 20, despite the fact that the host CPU 12 merely generates an asynchronous access signal.

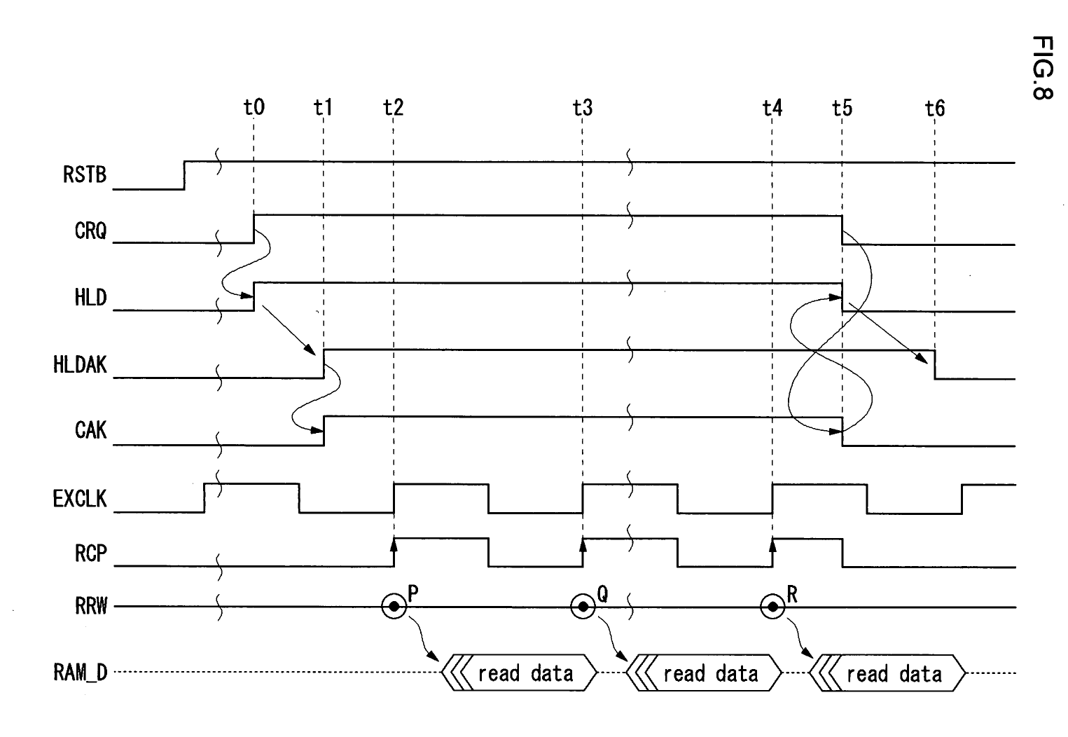

FIG. 8 is a timing chart illustrating the operation for access from the camera module 14 to the RAM 30. At initialization, RSTB goes low to become active. When the initialization is complete, RSTB returns to high. With this, the arbiter 32 and the subsidiary access circuit 26 are initialized. Subsequently, at time t0, an access request from the camera module 14 is generated. CRQ goes from low to high at time t0. In response to this, HLD goes from low to high. HLD is output to the host CPU 12. The host CPU 12 responds to HLD so as to cause HLDAK to go from low to high at time t1. In response to this, CAK goes from low to high. Since CAK becomes active as a result of the above steps, the entity accessing the memory is switched from the host CPU 12 to the camera module 14.

As a result of CAK going high, EXCLK appears as RCP. Consequently, RCP goes from low to high at time t2 to provide an edge of a synchronous signal. At this point of time, RRW is high, as illustrated in FIG. 8, so that a read cycle is initiated at time t2 (point P in the figure). Read data output from the RAM 30 is asserted on RAM_D after a predetermined access elapses since time t2. Similarly, RCP forms a rising edge at time t3 and time t4. Therefore, read cycles are initiated at time t3 and time t4 (points Q and R in the figure). Read data is asserted after a predetermined access time elapses. When data access from the camera module 14 is terminated, CRQ goes from high to low at time t5. In response to this, CAK goes from high to low. As a result, HLD goes from high to low. Subsequently, the host CPU 12 causes HLDAK to change from high to low at time t6 so that the accessing entity is switched back to the host CPU 12.

Described above is a description of the embodiment of the present invention. The embodiment is only illustrative in nature and it will be obvious to those skilled in the art that a variety of applications and variations of the embodiment are possible. The following is a description of some variations.

In the described embodiment, the clock signal used by the subsidiary access circuit 26 is input from an external source. However, the clock signal may be generated inside the memory control apparatus 20. For example, the clock signal may be generated by a ring oscillator or the like. In this case, the input of an external clock signal is of course unnecessary.

In the described embodiment, the subsidiary access circuit 26 generates RCP1 by simply ANDing CAK and EXCLK. With this approach, an undesired pulse may be created in RCP1 depending upon the timing relation between CAK and EXCLK. In this case, CAK may be latched in a flip-flop or the like so that RCP1 is generated using CLK synchronized with EXCLK using the rising edge or the falling edge of EXCLK.

In the described embodiment, the accessing entity is one of the host CPU 12, the camera module 14 and the LCD unit 16. These entities are merely by way of examples. A variety of other accessing entities and data processing entities may be assumed. For example, various multimedia functional blocks, circuits or apparatuses such as those for DSP may be such entities.

In the described embodiment, the RAM 30 is assumed to be a DRAM. The RAM 30 may of course be an arbitrary synchronous memory such as a SRAM.

In the described embodiment, the host CPU 12 is put on hold in order to acquire a right to use the bus from the host CPU 12. However, a variety of other methods are available, including an arrangement whereby the host CPU 12 is mad to wait.

### INDUSTRIAL USABILITY

The present invention is applicable to a memory control circuit and to an electronic apparatus using the circuit.

1. A memory control apparatus comprising:
a synchronous signal generating circuit which receives an asynchronous access signal output from an accessing entity that assumes an asynchronous memory not requiring a synchronous signal for access, and which generates a synchronous signal for a synchronous memory requiring a synchronous signal for access, by referring to a point of change in the asynchronous access signal; and
a primary access circuit which generates a synchronous access signal by processing the asynchronous access signal to fulfill a timing requirement required by the synchronous memory.

2. The memory control apparatus according to claim 1, further comprising:
an arbiter circuit which acquires a right to access to the synchronous memory for a data processing entity different from the access entity; and
a subsidiary access circuit which generates an access signal for the data processing entity to access the synchronous memory.

3. The memory control apparatus according to claim 2, wherein the subsidiary access circuit generates the access signal to access the synchronous memory, using a clock signal.

4. The memory control apparatus according to claim 1, wherein the synchronous signal generating circuit generates, in a read cycle, a synchronous signal so that an effective synchronous edge occurs after a relatively brief period of time elapses since the point of change, and generates, in a write cycle, a synchronous signal so that an effective synchronous edge occurs after a relatively long period of time elapses since the point of change.

5. An electronic apparatus comprising:
a host CPU;
a memory control apparatus;
an image capturing unit; and
a display unit, wherein
the memory control apparatus comprises:
a synchronous memory requiring a synchronous signal for access;
a circuit which receives an asynchronous signal from the host CPU and generates a synchronous signal required by the synchronous memory by generating a synchronous signal from the asynchronous signal;
a circuit which receives image data captured by the image capturing unit and writes the image data in the synchronous memory; and
a circuit which reads data from the synchronous memory and causes the display unit to display the read data.

6. The electronic apparatus according to claim 5, wherein the memory control apparatus further comprises an arbiter which performs arbitration for a right to use a bus between the host CPU and the image capturing unit.

7. The electronic apparatus according to claim 5, wherein the memory control apparatus further comprises an arbiter which performs arbitration for a right to use a bus between the host CPU and the display unit.

8. The electronic apparatus according to claim 5, wherein the image capturing unit does not acquire a right to use a bus on its own and allows the memory control apparatus to acquire a right to use the bus.

9. The electronic apparatus according to claim 5, wherein the unit does not acquire a right to use a bus on its own and allows the memory control apparatus to acquire a right to use the bus.
